(19) United States
(12) Patent Application Publication
(10) Pub. No.: US 2026/0075798 A1
(43) Pub. Date: Mar. 12, 2026

(54) Memory Circuitry And Methods Used In Forming Memory Circuitry

(71) Applicant: Micron Technology, Inc., Boise, ID (US)

(72) Inventors: Kevin Baker, Boise, ID (US); Protyush Sahu, Boise, ID (US); Radhakrishnan Padmanabhan, Boise, ID (US); Silvia Borsari, Boise, ID (US)

(73) Assignee: Micron Technology, Inc., Boise, ID (US)

(21) Appl. No.: 19/222,055

(22) Filed: May 29, 2025

Related U.S. Application Data
(60) Provisional application No. 63/692,798, filed on Sep. 10, 2024.

(51) Int. Cl. H10B 12/00; H10D 30/01; H10D 62/10; H10D 62/17; H10D 62/40; H10D 62/60; H10D 62/83; H10D 64/27

(52) U.S. Cl. CPC H10B 12/315; H10B 12/34; H10B 12/482; H10D 30/026; H10D 62/116; H10D 62/292; H10D 62/40; H10D 62/60; H10D 62/83; H10D 64/513

(57) ABSTRACT

A method includes forming pillars that project upwardly from a substrate and comprise conductively-doped monocrystalline semiconductive material. The pillars comprise either one source/drain region or another source/drain region of a transistor of individual memory cells of the memory circuitry being formed. Conductively-doped monocrystalline semiconductor material is grown from a top and sidewalls of the pillars to form conductive monocrystalline coverings that are individually directly above the top and circumferentially about the sidewalls of the individual pillars. Digitlines are formed that are individually above and directly electrically coupled to a plurality of the individual pillars of the another source/drain regions through the epitaxially-grown conductive monocrystalline covering that is directly there-above. Storage elements are formed to be above and electrically coupled to the individual pillars of the one source/drain regions through the epitaxially-grown conductive monocrystalline covering that is directly there-above. Structures are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIGS. 1-7 are diagrammatic cross-sectional views of a portion of a DRAM construction in fabrication in accordance with some embodiments of the invention.

FIGS. 8-47 are diagrammatic sequential sectional views of the construction of FIGS. 1-7 in subsequent processing, or alternate embodiments, in accordance with some embodiments of the invention.

### DETAILED DESCRIPTION OF EXAMPLE EMBODIMENTS

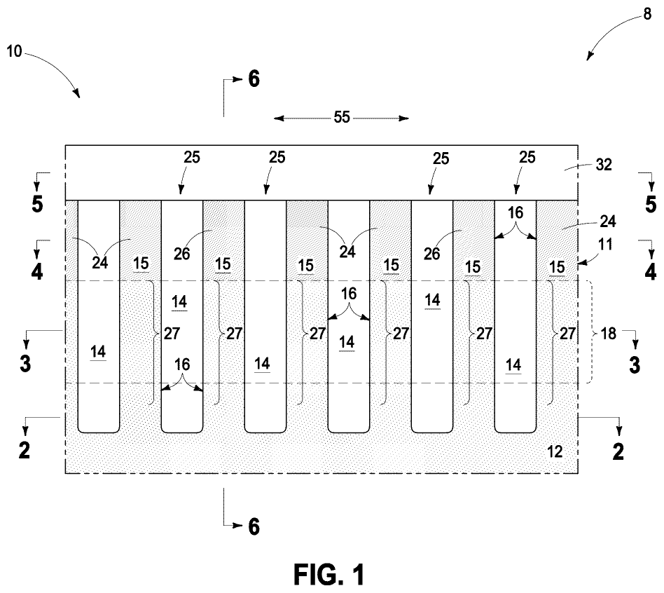

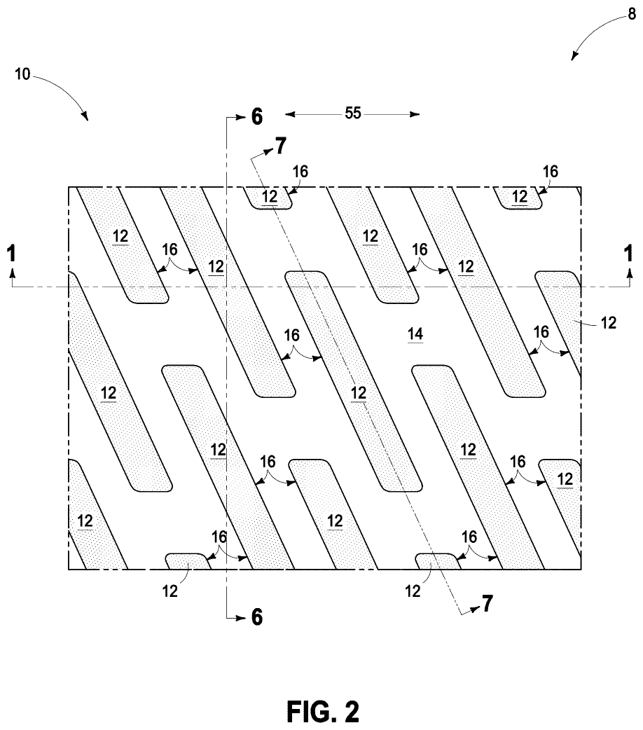

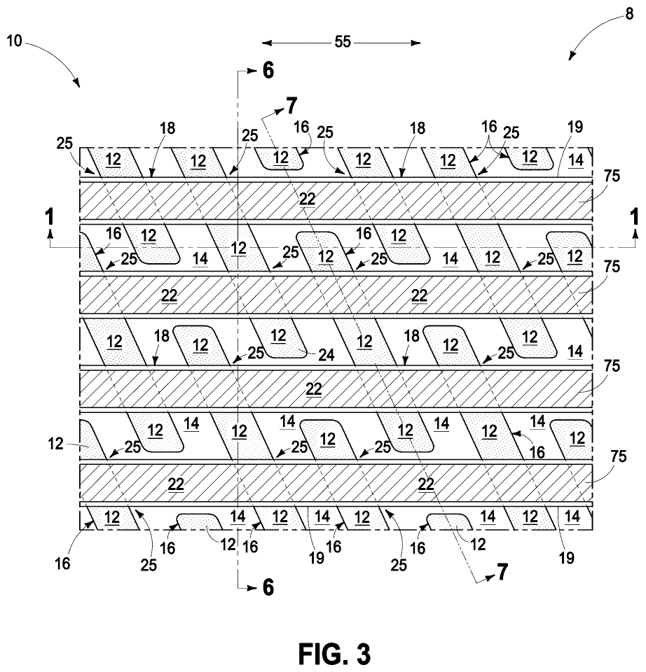

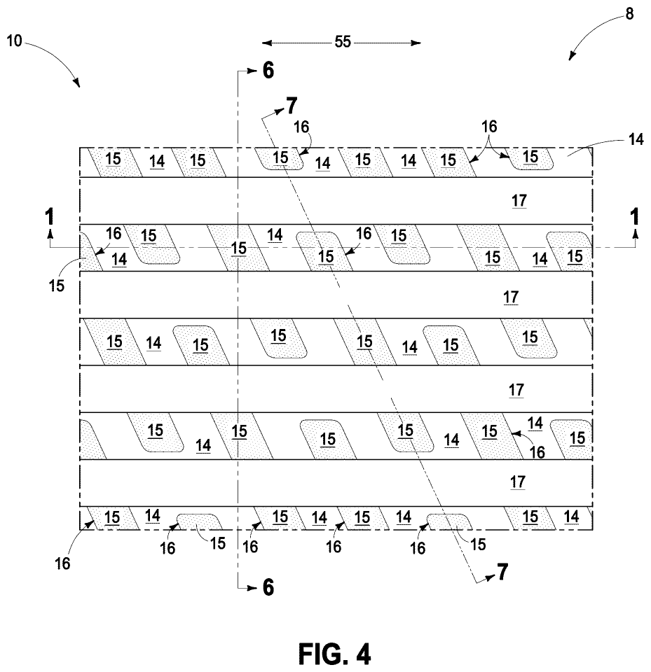

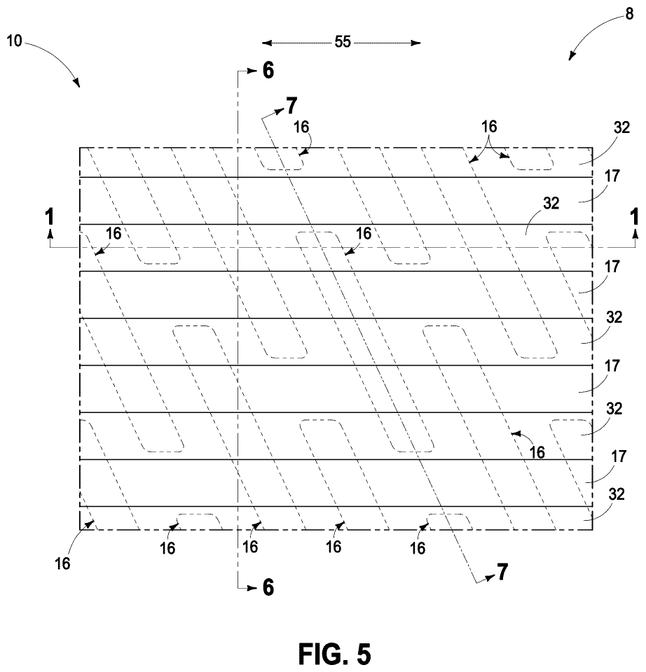

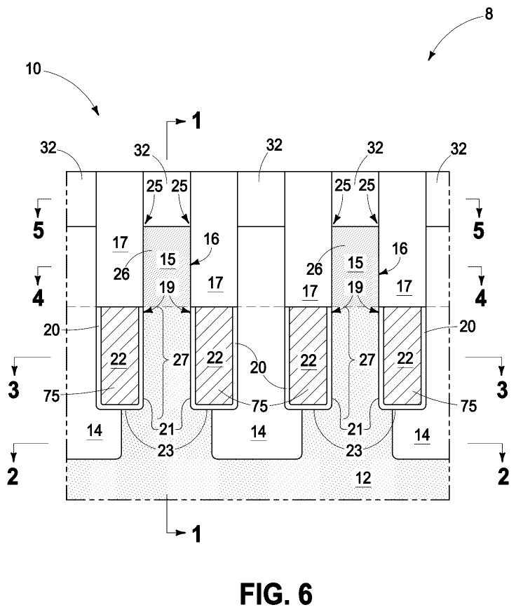

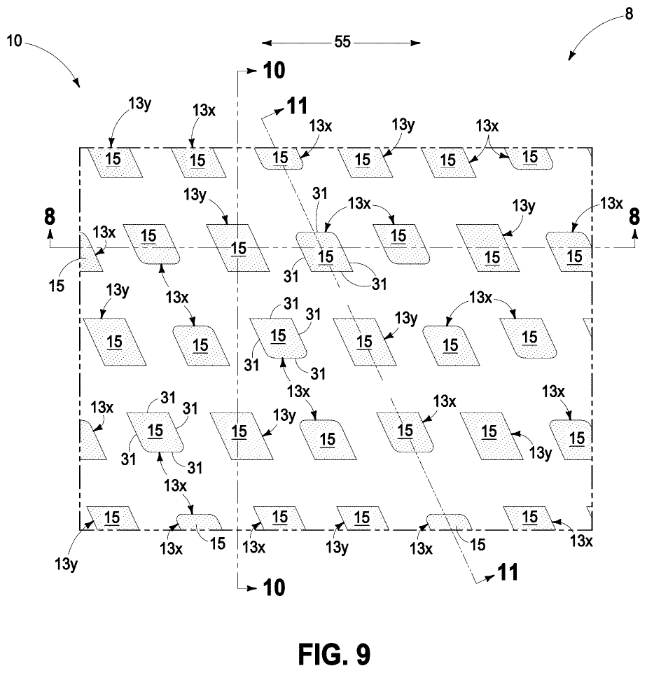

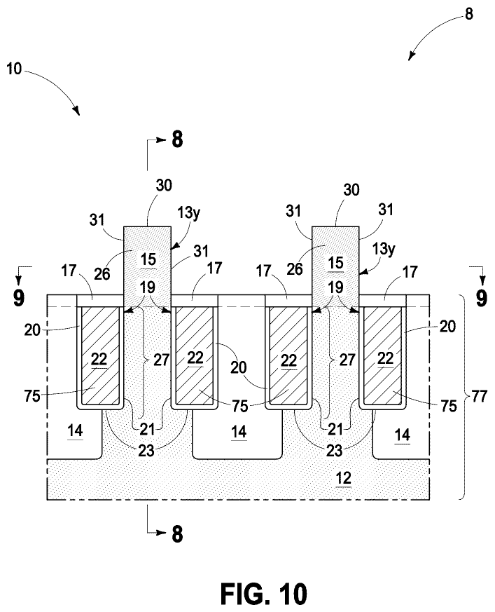

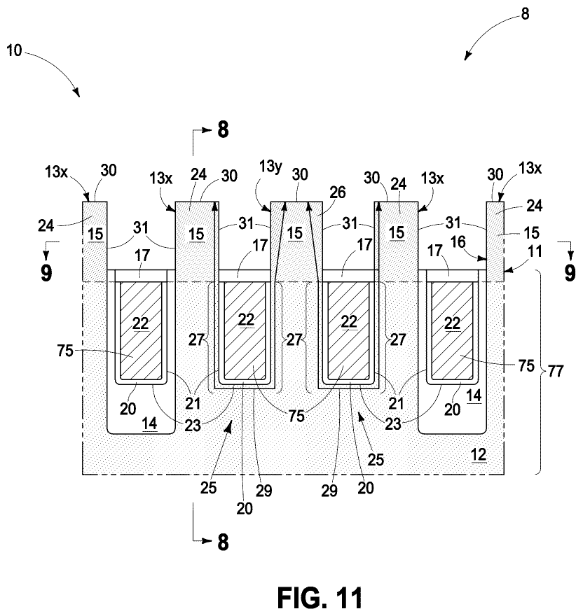

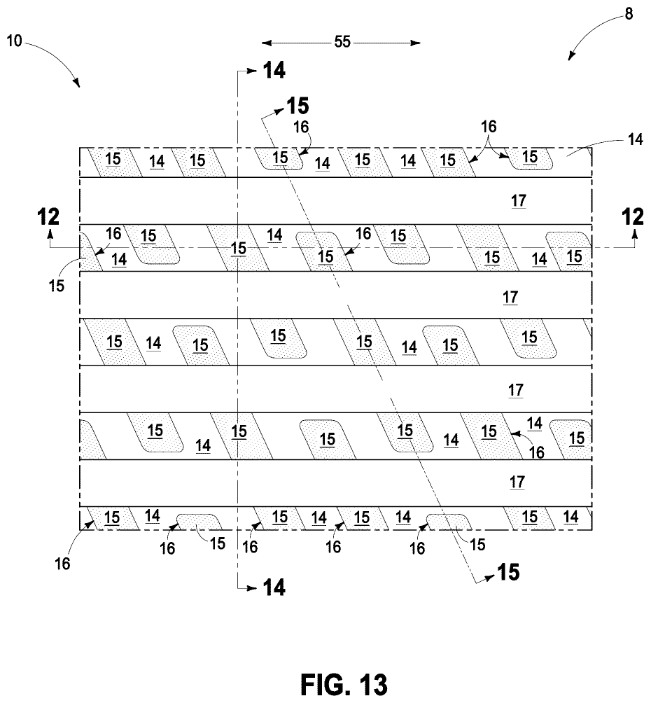

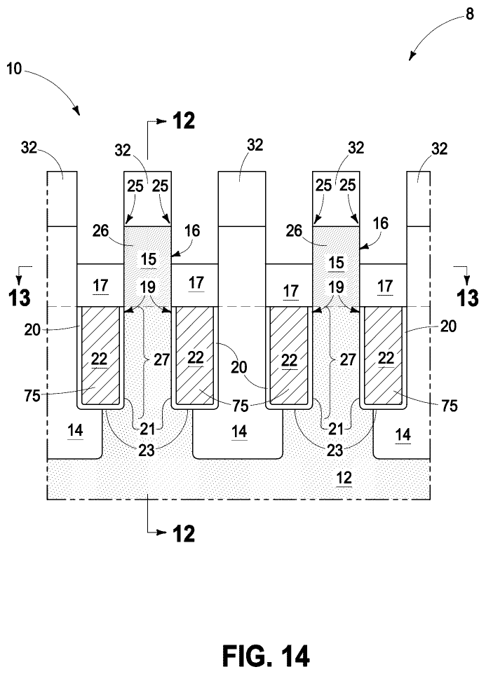

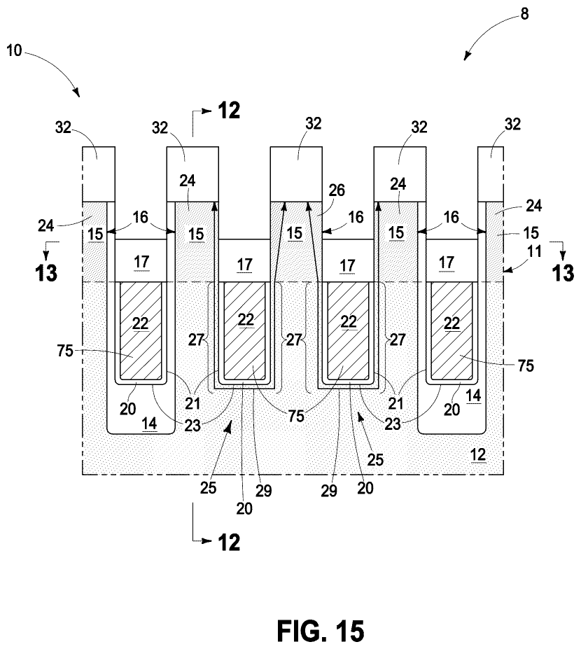

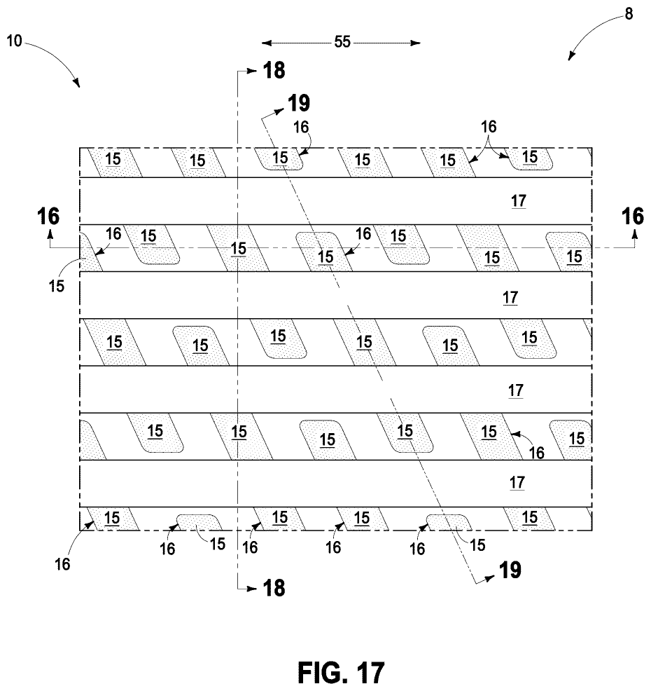

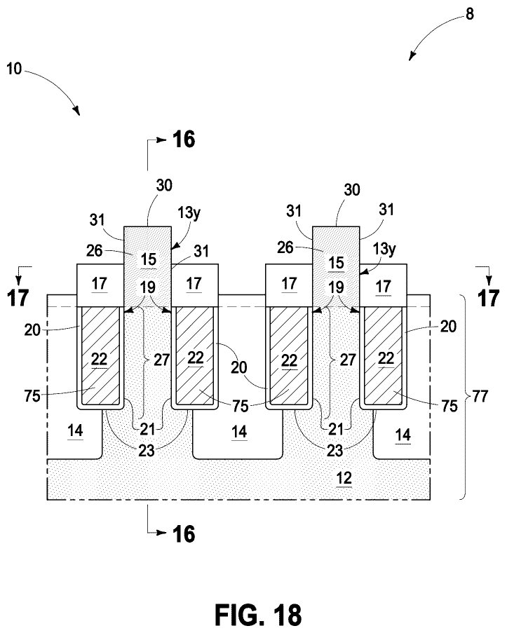

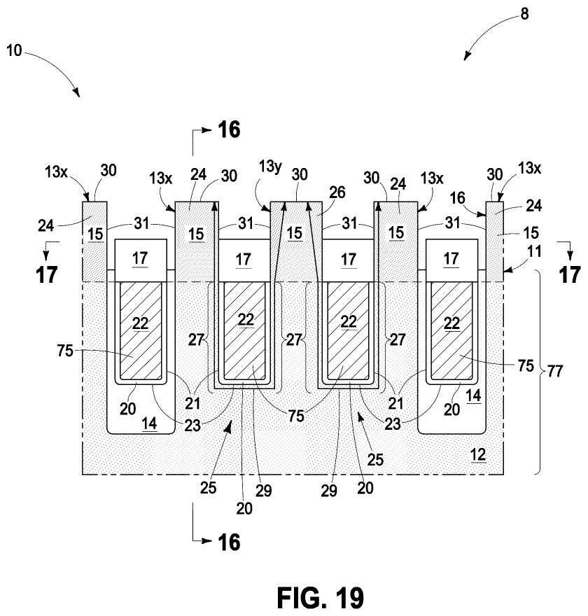

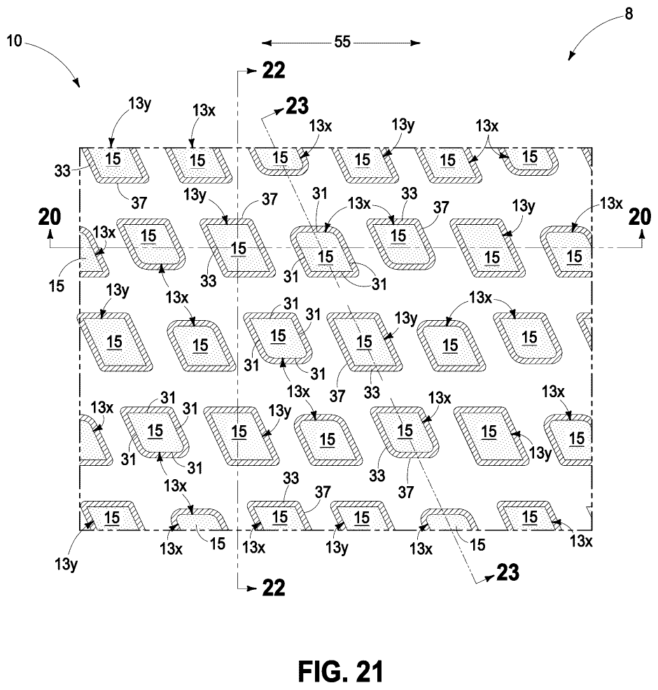

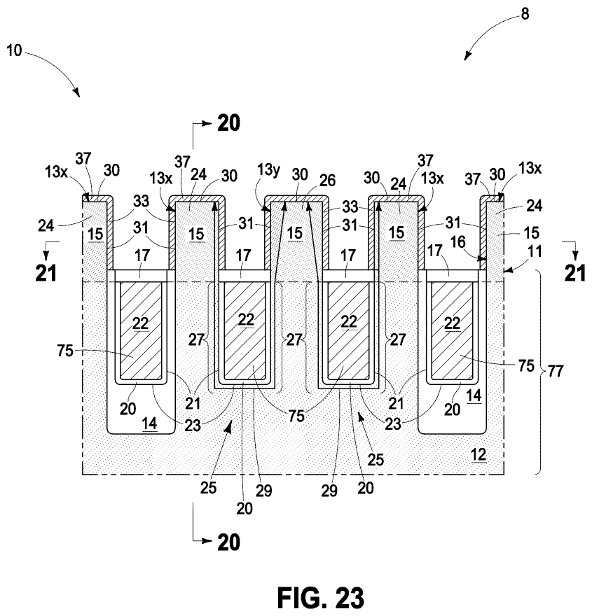

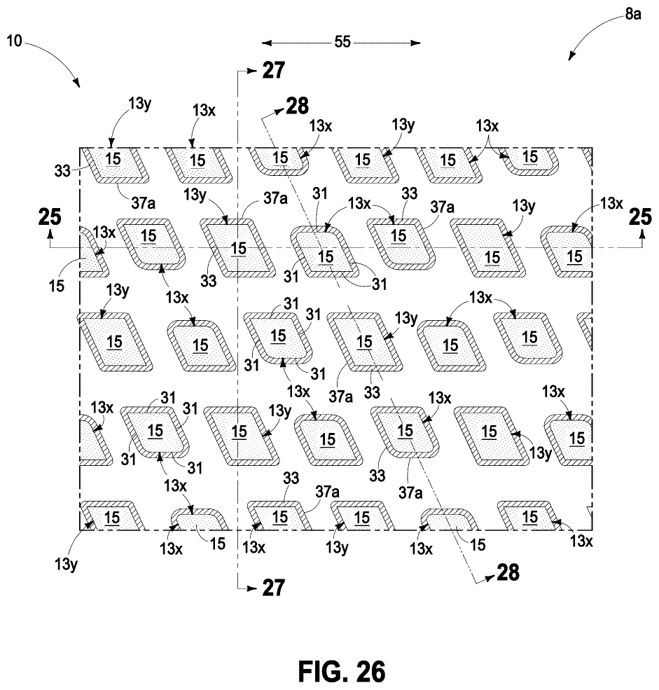

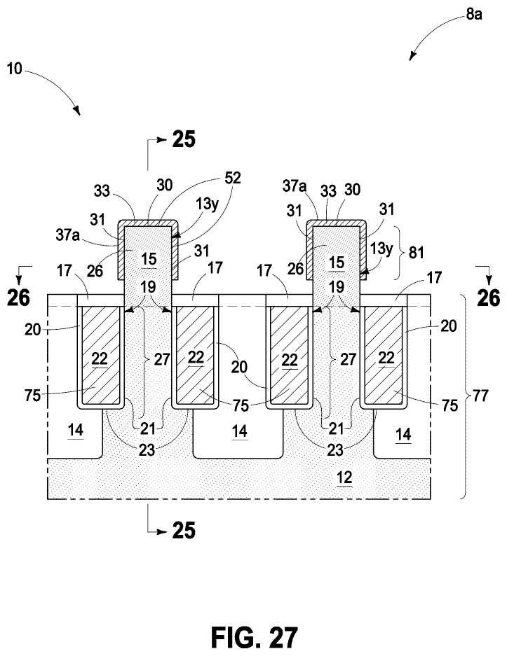

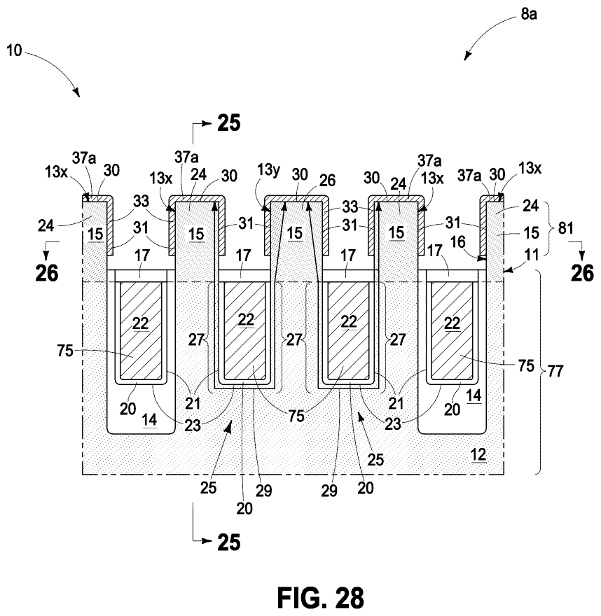

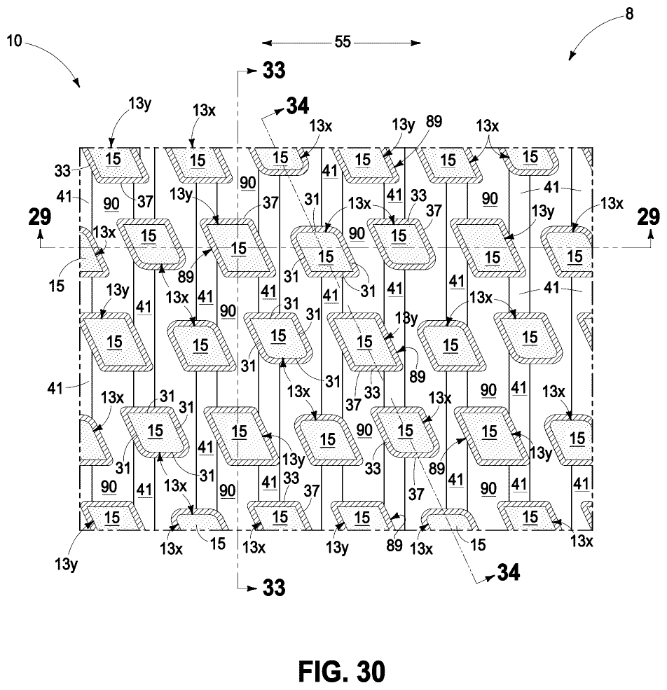

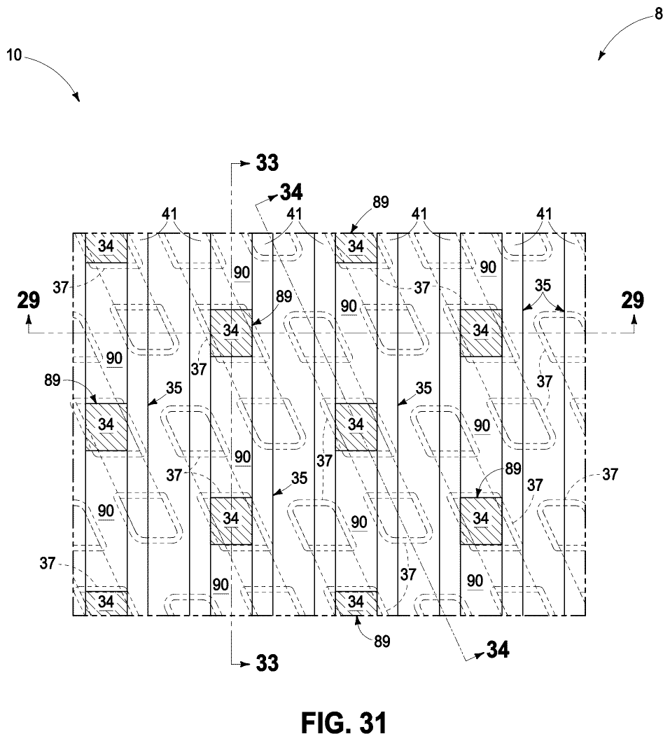

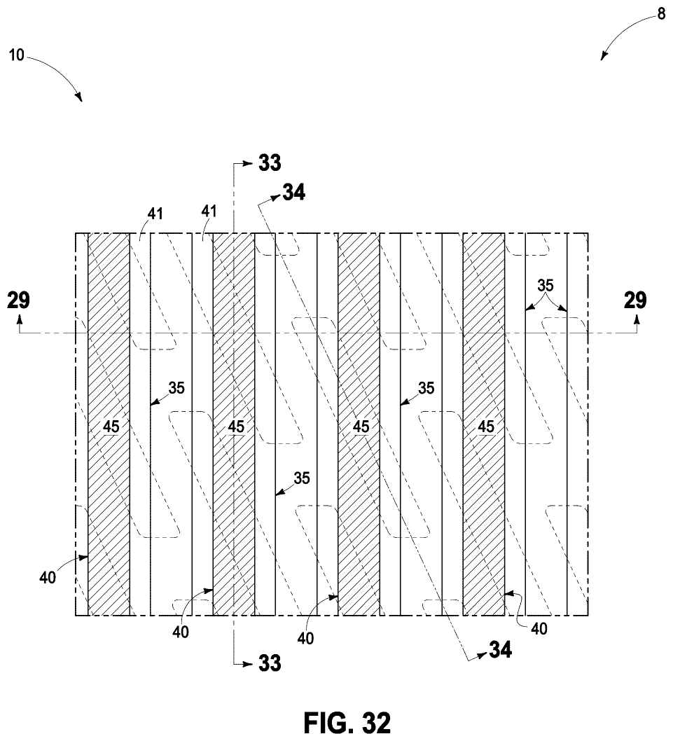

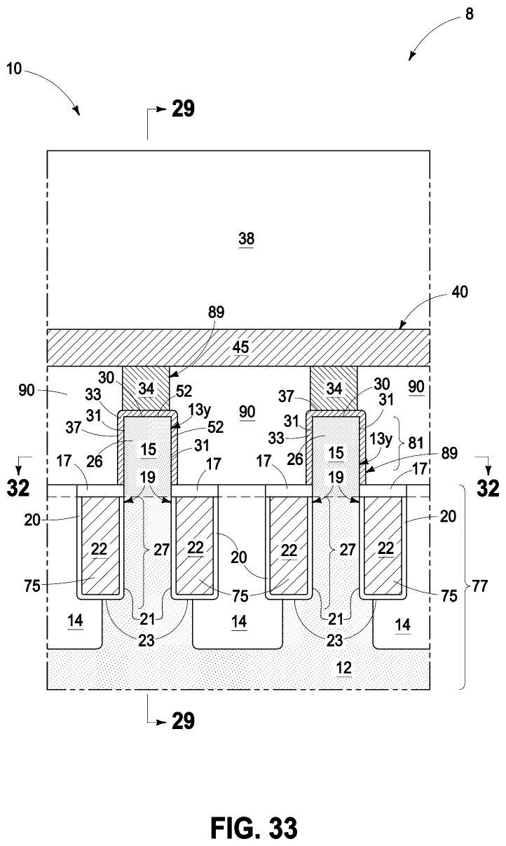

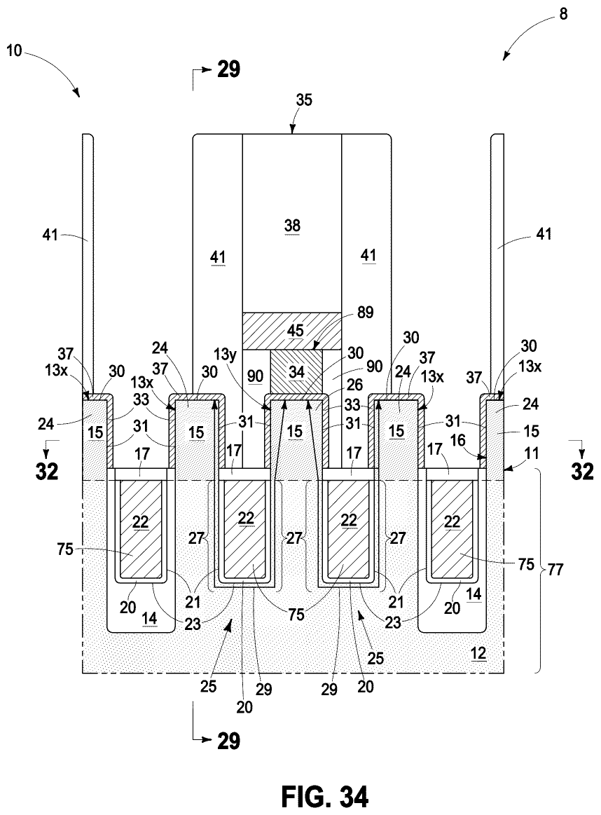

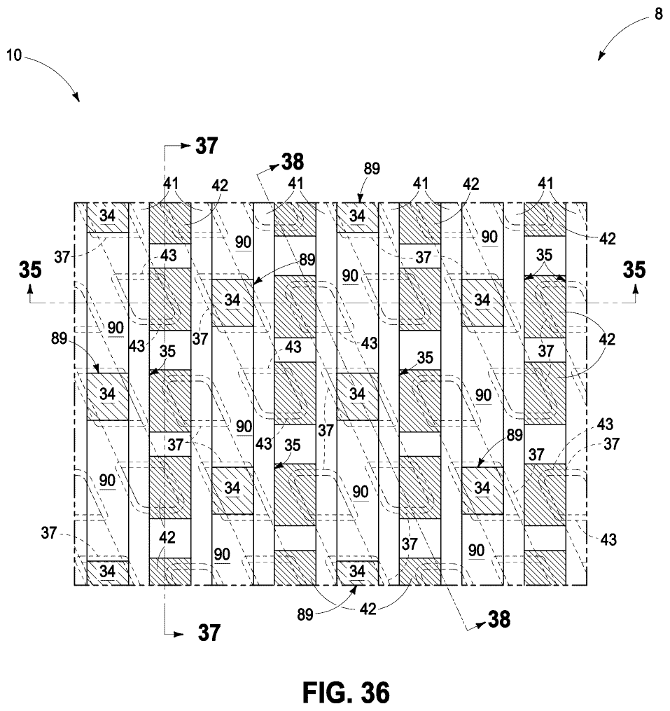

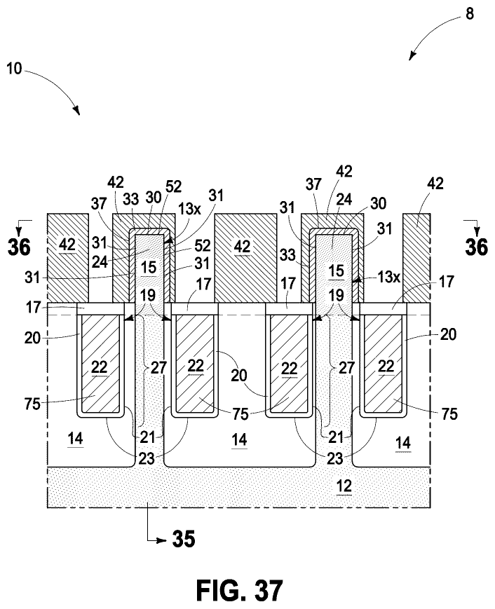

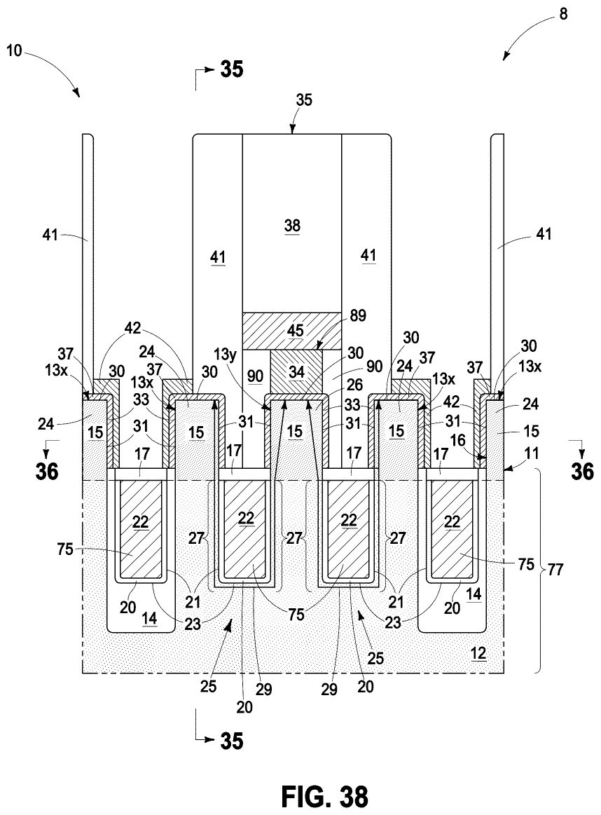

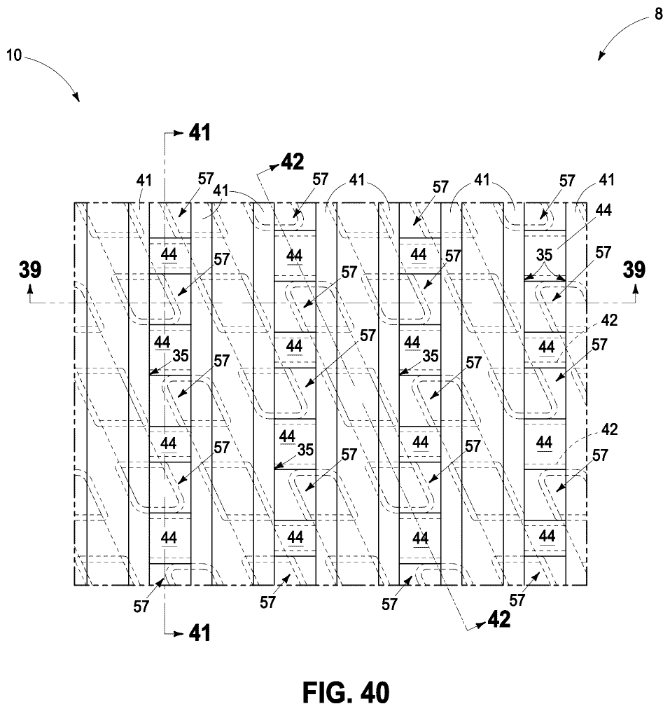

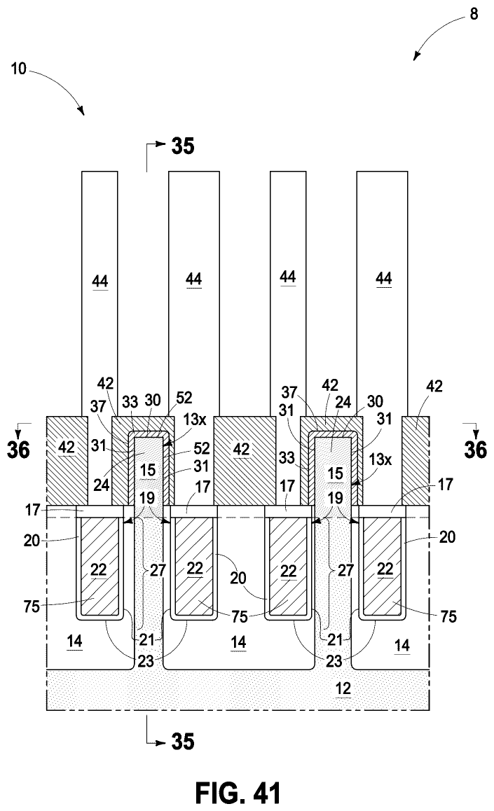

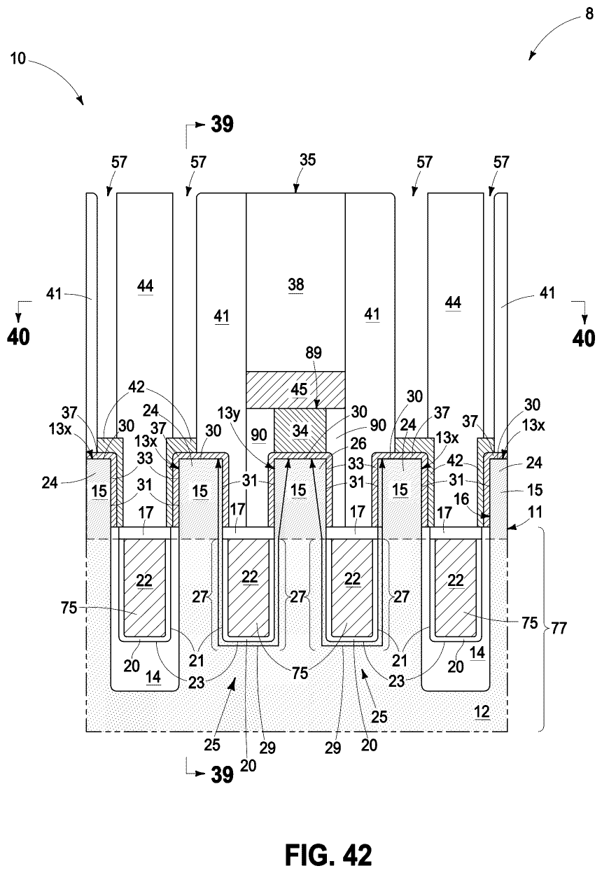

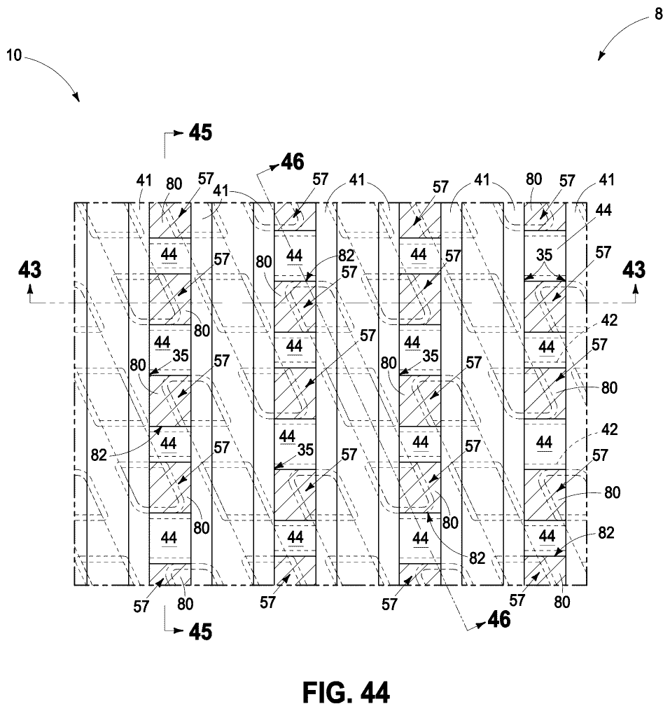

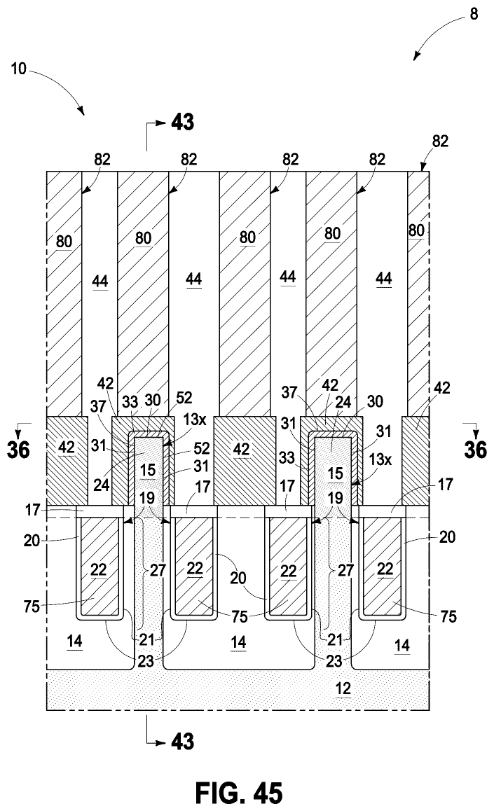

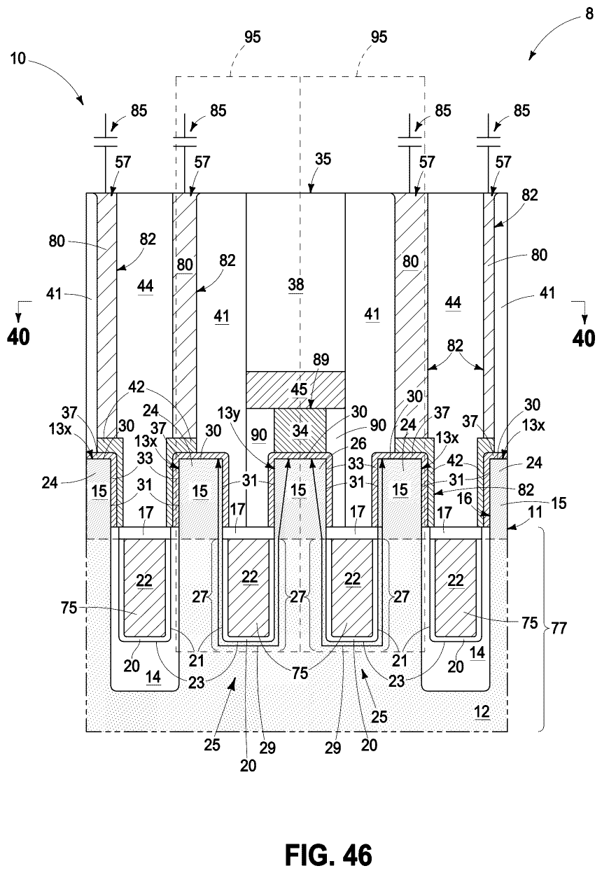

Example embodiments are described with reference to FIGS. 1-47. FIGS. 1-7 show an example fragment of a substrate construction 8 comprising an array or array area 10 in the process of fabrication relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 1-7—depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Base substrate 11 comprises semiconductive material 12 (e.g., appropriately and variously doped monocrystalline and/or polycrystalline silicon, Ge, SiGe, GaAs, and/or other existing or future-developed semiconductive material), trench isolation regions 14 (e.g., silicon nitride and/or silicon dioxide), and active area regions 16 comprising suitably and variously-doped semiconductive material 12. Construction 8 comprises transistors 25 individually comprising one source/drain region 24 and another source/drain region 26, a channel region 27 between the one and the another source/drain regions, and a conductive gate 22 (e.g., conductively-doped semiconductor material and/or metal material, including for example elemental W, Ru, and/or Mo) operatively proximate channel region 27 (e.g., a gate insulator 20 being between the conductive gate 22 and channel region 27, for example silicon dioxide and/or silicon nitride). Conductive gate 22 comprises part of one of a plurality of conductive-gate lines 75 in substrate 11 and that extend along a row direction 55. Transistors 25 are shown as being recessed access devices, with example construction 8 showing such recessed access devices grouped in individual pairs of such devices. Individual recessed access devices/transistors 25 include a buried access line construction 18, for example that is within a trench 19 in semiconductive material 12. Construction 18 comprises conductive gate 22. Gate insulator 20 is along sidewalls 21 and a base 23 of individual trenches 19 between conductive gate 22 and semiconductive material 12. Insulative material 17 (e.g., silicon dioxide and/or silicon nitride) is within trenches 19 above materials 20 and 22. One source/drain region 24 and another source/drain region 26 are in upper portions of semiconductive material 12 on opposing sides of individual trenches 19 (e.g., regions 24, 26 being laterally-outward of and higher than access line constructions 18). Each of source/drain regions 24, 26 has at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁸ atoms/cm³). Accordingly, all or only a part of each source/drain region 24, 26 may have such maximum concentration of conductivity-increasing dopant. One source/drain region 24 and another source/drain region 26 comprise conductively-doped monocrystalline semiconductive material 15 (e.g., a conductively-doped portion of a monocrystalline semiconductive material 12; e.g., predominantly at least one of silicon or germanium that is conductively-doped to be n-type or p-type conductive). Source/drain regions 24 and/or 26 may include other doped regions (not shown), for example halo regions, LDD regions, etc.

In the example embodiment, one of the source/drain regions (e.g., another source/drain region 26) of the pair of source/drain regions in individual of the pairs of transistors 25 is laterally between conductive gates 22 and is shared by the pair of devices/transistors 25. Others of the source/drain regions (e.g., one source/drain region 24) of the pair of source/drain regions are not shared by the pair of transistors 25. Thus, in the example embodiment, each active area region 16 comprises two transistors 25 (e.g., one pair of transistors 25), with each sharing a central source/drain region 26.

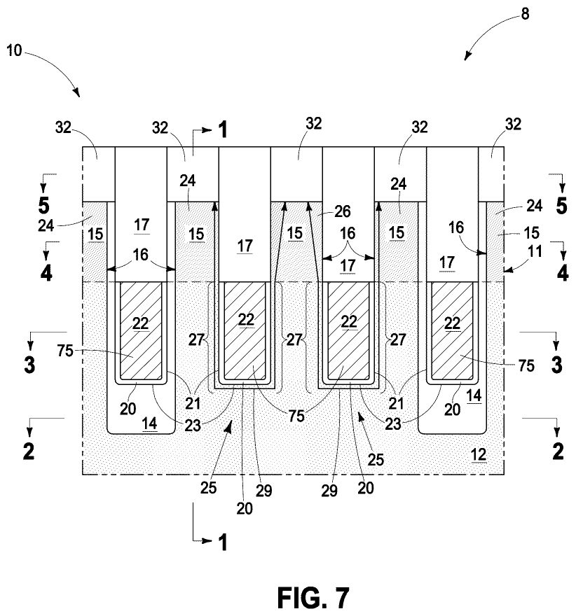

Example channel region 27 is in semiconductive material 12 below pair of source/drain regions 24, 26 along trench sidewalls 21 and around trench base 23. Channel region 27 may be undoped or may be suitably doped with a conductivity-increasing dopant likely of the opposite conductivity-type of the dopant in source/drain regions 24, 26. When suitable voltage is applied to gate material 22 of an access line construction 18, a conductive channel forms (e.g., along a channel current-flow line/path 29 [FIG. 7]) within channel region 27 proximate gate insulator 20 such that current is capable of flowing between a pair of source/drain regions 24 and 26 under the access line construction 18 within an individual active area region 16. Stippling is diagrammatically shown to indicate primary conductivity-modifying dopant concentration (regardless of type), with denser stippling indicating greater dopant concentration and lighter stippling indicating lower dopant concentration. Conductivity-modifying dopant may be, and would likely be, in other portions of material 12 as shown. Only two different stippling densities are shown in material 12 for convenience, and additional dopant concentrations may be used, and constant dopant concentration is not required in any region.

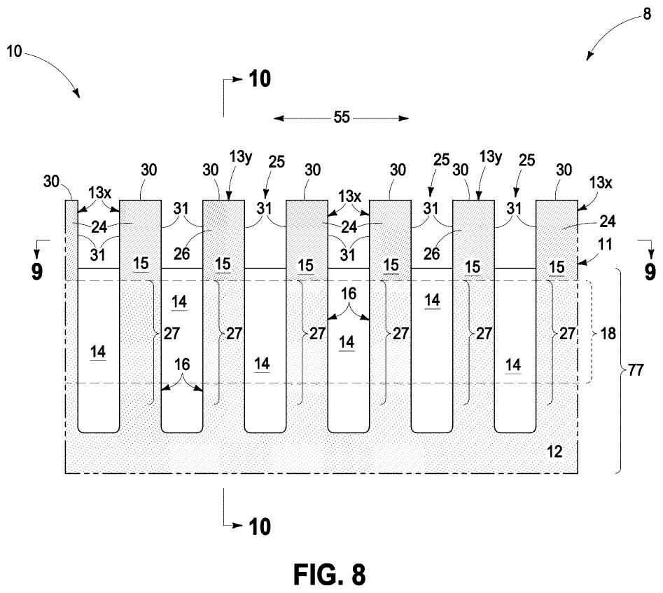

Referring to FIGS. 8-11, pillars 13* have been formed to project upwardly from a substrate 77 and comprise conductively-doped monocrystalline semiconductive material 15 (an * being used as a suffix to be inclusive of all such same-numerically-designated structures or portions thereof that may or may not have other suffixes). Individual of pillars 13* comprise either one source/drain region 24 (13x) or another source/drain region (13y) of a transistor 25 of individual memory cells of the memory circuitry being formed. Pillars 13* individually comprise a top 30 and sidewalls 31. In one embodiment and as shown, the forming of pillars 13* comprises removing (e.g., by etching) insulative material (e.g., 14 and 17) that surrounds conductively-doped monocrystalline semiconductive material 15 and in one embodiment that is atop such (e.g., 32). In one embodiment where the removing is by etching, the insulative material comprises silicon nitride (e.g., 17) and silicon dioxide (e.g., 14 and/or 32) and the etching comprises etching the silicon nitride and the silicon dioxide selectively relative to conductively-doped monocrystalline semiconductive material 15 at the same time using the same etching chemistry. The artisan is capable of choosing suitable etching chemistry(ies) and conditions to achieve such etching. For example, and by way of example only, silicon dioxide and silicon nitride can collectively/at-the-same-time be etched (e.g., at a volumetric rate of 0.95:1 to 1:1.05 relative one another) selectively relative to conductively-doped monocrystalline silicon 15 (e.g., at a volumetric rate of at least 10:1 relative one another) using SF₆ and Ar at 100° C. to 500° C. and at 10 m Torr to 5 Torr under plasma conditions.

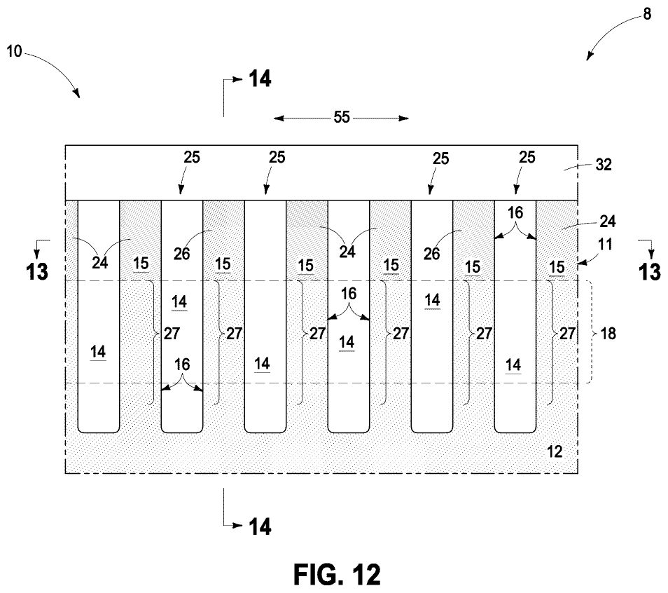

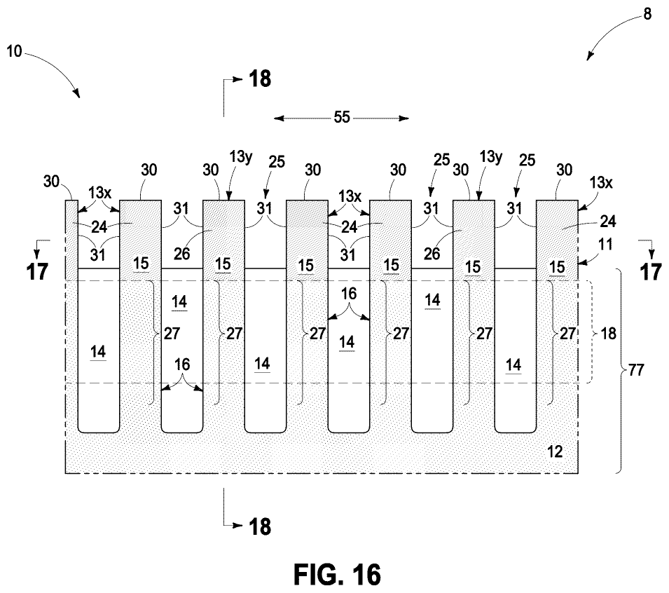

By way of example only, an alternate example of forming pillars 13* where etching is used and the insulative material comprises silicon nitride and silicon nitride is described with reference to FIGS. 12-19 and FIGS. 8-11. Such comprises temporal first, second, and third etchings. Etching may occur before, after, and/or between such etchings. FIGS. 12-15 show results from a first etching that removes some of the silicon nitride (e.g., 17) selectively relative to the silicon dioxide (e.g., 14 and 32) and conductively-doped monocrystalline semiconductive material 15 (e.g., using CF₄ and He with or without plasma generation). FIGS. 16-19 show results from a second etching that removes some of the silicon dioxide (e.g., 14 and 32) selectively relative to the silicon nitride (e.g., 17) and conductively-doped monocrystalline semiconductive material 15 (e.g., using NH₃ and NF₃ with plasma). FIGS. 8-11 show results from a third etching that removes another some of the silicon nitride (e.g., 17) selectively relative to the silicon dioxide (e.g., 14) and conductively-doped monocrystalline semiconductive material 15 (e.g., using CF₄ and He with or without plasma generation).

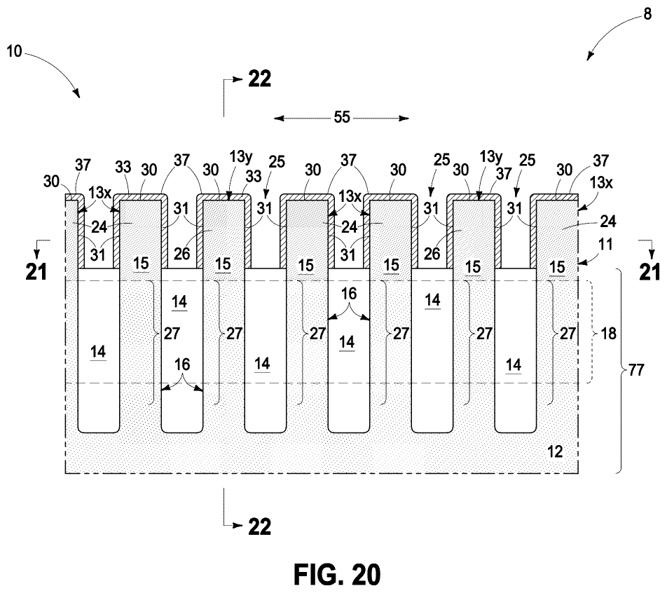

Referring to FIGS. 20-23, conductively-doped monocrystalline semiconductor material 33 has been epitaxially grown from top 30 and sidewalls 31 of individual pillars 13* to form conductive monocrystalline coverings 37 that are individually directly above top 30 and circumferentially about sidewalls 31 of individual pillars 13*. In structure embodiments, and which are independent of method attributes or limitations unless so stated in a claim, conductive monocrystalline coverings 37 that are above individual pillars 13x are at least part of a conductive-via construction and conductive monocrystalline coverings 37 that are above individual pillars 13y are at least part of a conducting-via construction. In one embodiment, the epitaxially growing forms conductive monocrystalline coverings 37 to at least predominantly have greater conductivity-increasing-dopant therein (e.g., by a factor of at least 10) than is at least predominantly in top 30 of individual pillars 13*. In one such embodiment, conductively-doped monocrystalline semiconductor material 33 and conductively-doped monocrystalline semiconductive material 15 are of the same composition but for quantity of the conductivity-increasing-dopant (e.g., such same composition at least predominantly comprising elemental silicon). As an example, conductivity-dopant concentration in one and another source/drain regions 24, 26 is 1×10¹⁸ atoms/cm³ to 1×10²⁰ atoms/cm³ and in conductive monocrystalline coverings 37 is 1×10²¹ atoms/cm³ to 1×10²³ atoms/cm³.

The artisan is capable of selecting suitable conditions for epitaxially growing conductively-doped monocrystalline semiconductor material 33 depending on its composition. For example, and by way of example only, monocrystalline silicon surfaces of pillars 13* may be prepared for epitaxial growth be exposure to NH₃ and NF₃ using remote plasma to form a precursor that reacts with silicon of such surfaces to form adherent [NH₄]₂SiF₆. Such may be largely if not completely removed from pillars 13* using a suitable etchant, followed by using dichlorosilane, HCl, and phosphine at temperature of 500° C. to 800° C. and pressure of 5 Torr to 500 Torr to form conductively n-type-doped monocrystalline silicon 33.

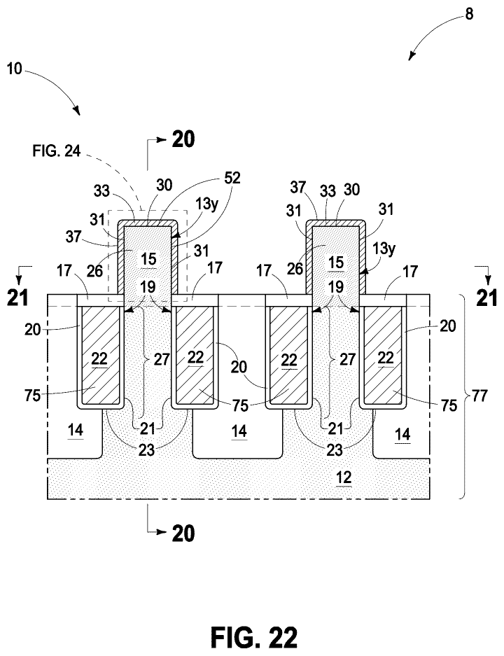

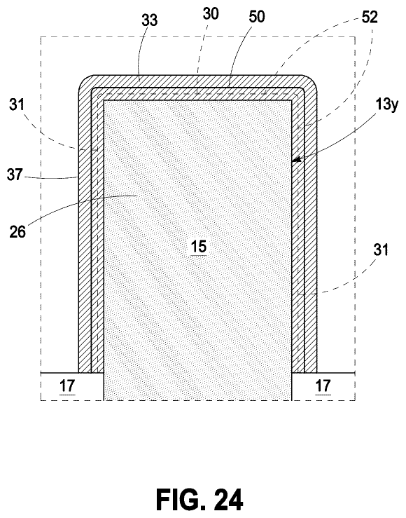

In one embodiment and referring to FIGS. 22 and 24, the epitaxially growing forms an intermediate region 50 at an interface 52 of individual conductive monocrystalline coverings 37 with top 30 and sidewalls 31 of its pillar 13*, with intermediate region 50 comprising chlorine, fluorine, and nitrogen individually at 1×10¹⁵ atoms/cm³ to 5×10²¹ atoms/cm³. Intermediate region 50 and the chlorine, fluorine, and nitrogen therein may result from incomplete removal of the example [NH₄]₂SiF₆ and from use of dichlorosilane and HCl for the epitaxial growth as referred to above. By way of example only, an example thickness of intermediate region 50 is 2 to 3 nanometers.

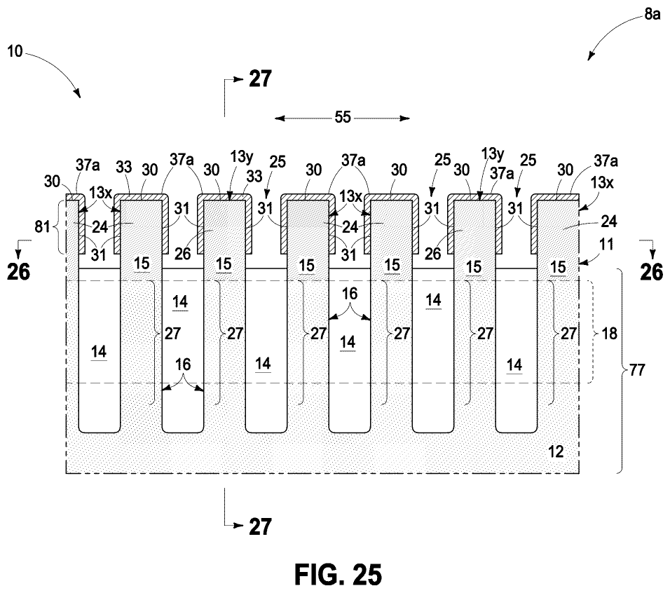

In one embodiment and as shown, the epitaxially growing forms conductive monocrystalline covering 37 along a total of elevational length of sidewalls 31 of the pillars 13* that are above substrate 77. An alternate example is shown with respect to a construction 8a in FIGS. 25-28. Like numerals from the above-described embodiments have been used where appropriate, with some construction differences being indicated with the suffix “a”. In FIGS. 25-28, the epitaxially growing forms conductive monocrystalline covering 37a only along an uppermost portion 81 of sidewalls 31 of pillar 13* that are above substrate 77 and thereby along less than a total of elevational length of sidewalls 31 of pillars 13* that are above substrate 77. Such may result, for example, if less than all of sidewalls are prepared for epitaxial growth using NH₃ and NF₃ if such do not get to the bottom of pillars 13* and/or if the epitaxial growth precursors do not get to the bottom of pillars 13*.

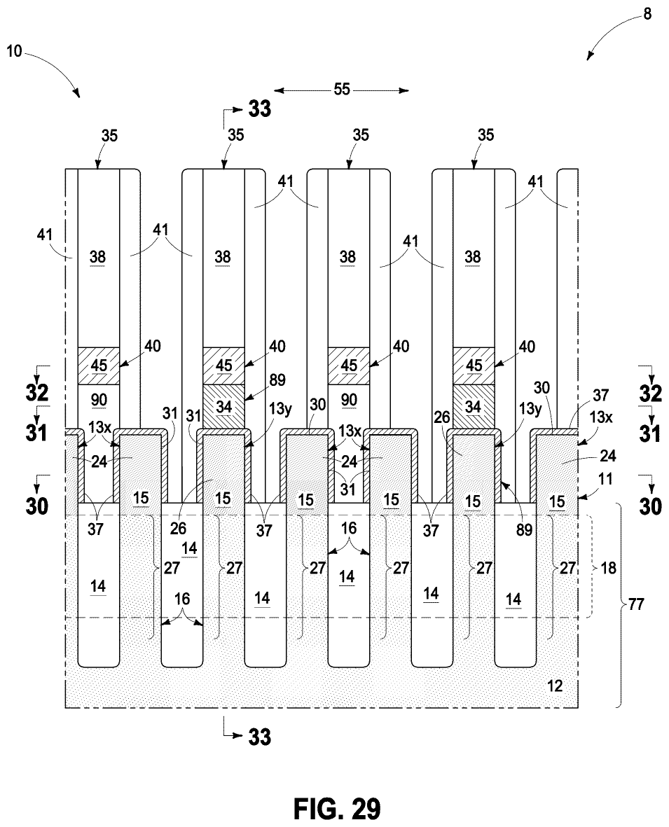

Referring to FIGS. 29-34, and in one embodiment, digitline structures 35 have been formed. Such individually comprise a conductive digitline 40 (e.g., comprising conductive metal material 45) that is above and directly electrically coupled to a plurality of individual pillars 13y of another source/drain regions 26 through epitaxially-grown conductive monocrystalline covering 37 that is directly there-above (i.e., that is directly above its pillar 13y). Example digitline structures 35 include insulative material 90 (e.g., silicon nitride and/or silicon dioxide) there-along between immediately-adjacent conductive monocrystalline covering 37. Example digitline structures 35 also include example conducting material 34 (e.g., conductive metal material) that directly electrically couples digitlines 40 with individual conductive monocrystalline coverings 37, and thereby comprise conducting-via constructions 89 that include conducting material 34 and conductive monocrystalline coverings 37. Example digitline structures 35 also comprise an insulator material 38 atop digitlines 40 and anisotropically-etched insulative sidewall spacers 41 (e.g., silicon nitride and/or silicon dioxide) on each side thereof. Spacers 41 may individually comprise multiple different composition materials some or each of which may be separately anisotropically etched.

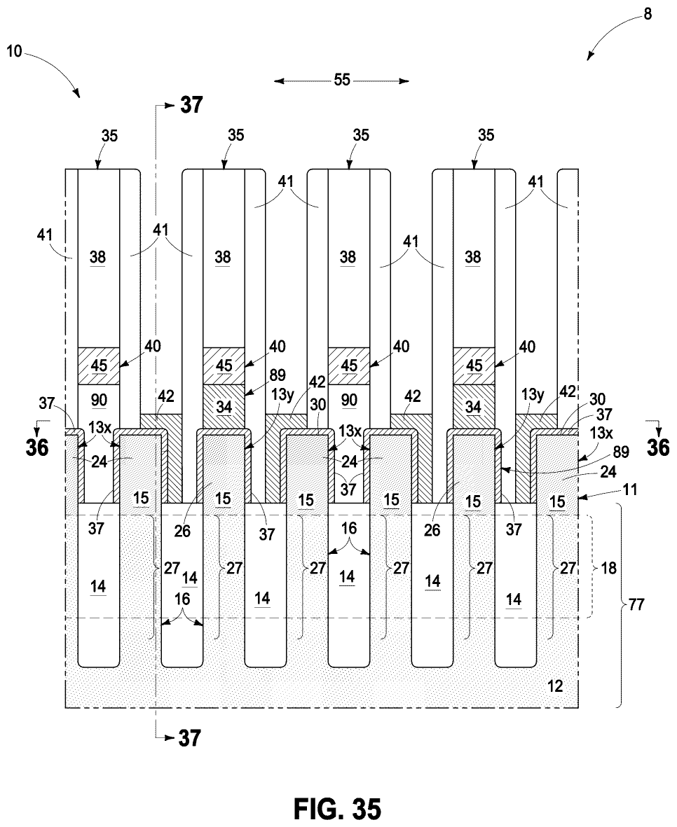

Storage elements of individual memory cells are ultimately formed. Such storage elements individually are above and electrically coupled (e.g., directly electrically coupled) to the individual pillars of the one source/drain regions through the epitaxially-grown conductive monocrystalline covering 37 that is directly there-above. In one such embodiment, conducting material is formed prior to forming the storage elements such that such conducting material is vertically between one of the storage elements and its conductive monocrystalline covering 37, with such conducting material being directly above and directly electrically coupled to its conductive monocrystalline covering 37 and being of different composition from that of its conductive monocrystalline covering 37. One such example is next-described with respect to FIGS. 35-46.

Referring to FIGS. 35-38, and in one embodiment, conductively-doped semiconducting material 42 has been formed atop conductively-doped monocrystalline semiconductor material 33 of individual conductive monocrystalline coverings 37. By way of examples, material 42 may be deposited directly against material 33 and subtractively etched, or material 42 may be epitaxially grown from material 33 (ideal). Materials 42 and 33 may be of the same or different composition(s) relative one another. Regardless, and in one such embodiment as shown, conductively-doped semiconducting material 42 extends laterally-outward beyond a side 43 of epitaxially-grown conductively-doped monocrystalline semiconductor material 33 of conductive monocrystalline coverings 37 (e.g., beyond two opposing sides 43 as shown).

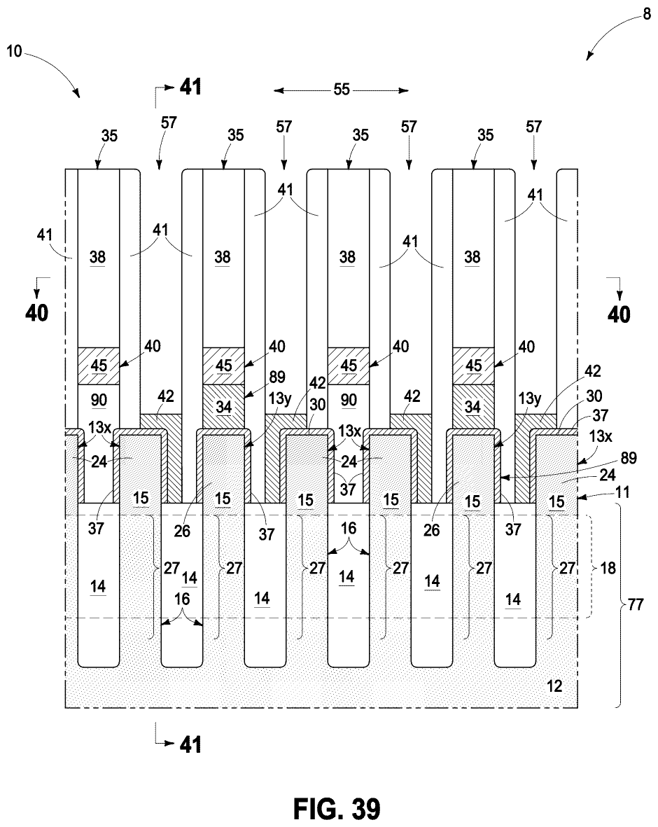

Referring to FIGS. 39-42, insulative material 44 (e.g., silicon dioxide and/or silicon nitride) has been formed between digitline structures 35 and contact openings 57 have then been formed there-through to conductively-doped semiconducting material 42. Insulative material 44 may be planarized back to the tops of material 38 (as shown). Contact openings 57 may taper laterally inward and/or laterally outward (not shown). Contact openings 57 in horizontal cross-section may be of the same size and/or shape that of material 42 and/or 33 (roughly same shape, but different size, as material 42 being shown). In embodiments where conductively-doped semiconducting material 42 is formed, such may be formed before or after forming insulative material 44 with its contact openings 57.

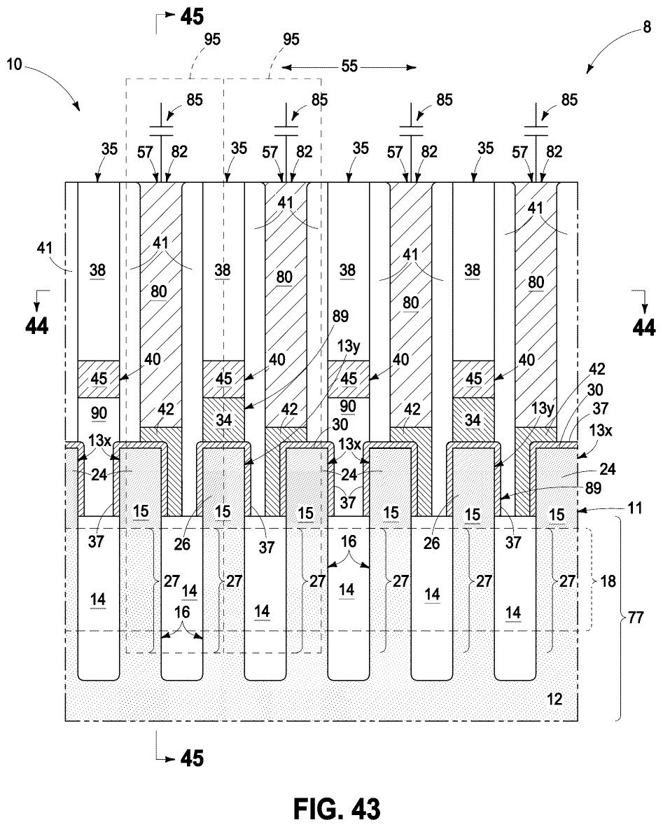

Referring to FIGS. 43-46, conductive metal material 80 has been formed directly above and directly against conductively-doped semiconducting material 42, thus forming individual conductive-via constructions 82 (e.g., comprising materials 80, 42, and 33/covering 37). Storage elements 85 (e.g., capacitors) have been formed (e.g., directly electrically coupled to individual conductive-via constructions 82), thus forming individual memory cells 95 (e.g., that comprise a transistor 25 and a storage element 85). Such is but one example embodiment where storage elements 85 are individually above and electrically coupled (e.g., directly coupled) to individual one source/drain regions 24 through individual conductive monocrystalline coverings 37 that comprise epitaxially-grown conductively-doped monocrystalline semiconductor material 33.

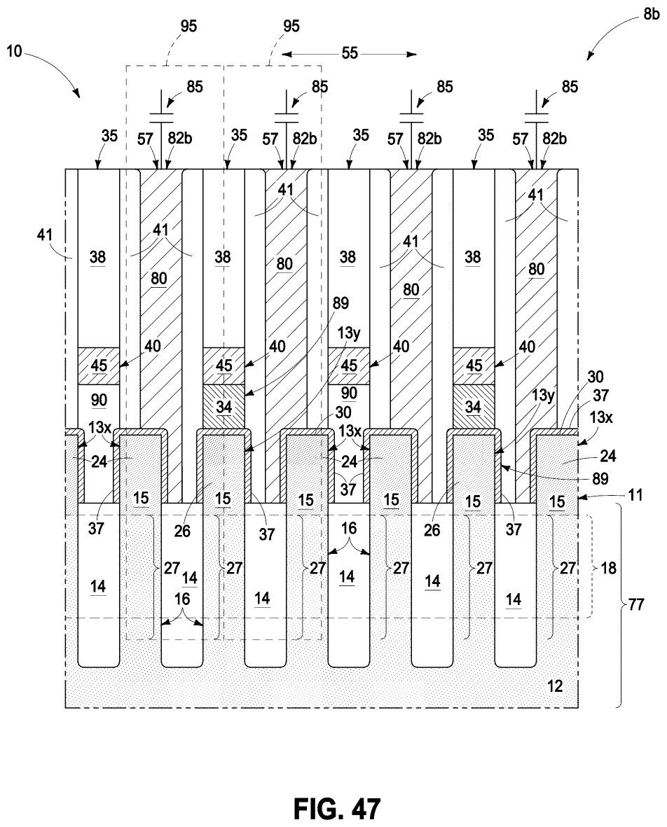

FIG. 47 shows an example alternate construction 8b comprising conductive-via constructions 82b (e.g., comprising materials 80 and 33/covering 37) that are devoid of conductively-doped semiconducting material 42 (such thereby not being shown). Like numerals from the above-described embodiments have been used where appropriate, with some construction differences being indicated with the suffix “b”.

Any other attribute(s) or aspect(s) as shown and/or described herein with respect to other embodiments may be used in the embodiments shown and described with reference to the above embodiments.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 8, 8b) comprises transistors (e.g., 25) individually comprising one source/drain region (e.g., 24) and another source/drain region (e.g., 26). The one and another source/drain regions individually comprise a pillar (e.g., 13*) comprising conductively-doped monocrystalline semiconductive material (e.g., 15). The pillar comprises a pillar top (e.g., 30) and pillar sidewalls (e.g., 31). A channel region (e.g., 27) is between the one and the another source/drain regions. A conductive gate (e.g., 22) is operatively proximate the channel region. Conducting-via constructions (e.g., 89) are included and are individually directly above and directly electrically coupled to the pillar of individual of the another source/drain regions. Digitlines (e.g., 40) are individually above and directly electrically coupled to a plurality of the conducting-via constructions. Conductive-via constructions (e.g., 82) are included and are individually directly above and directly electrically coupled to the pillar of individual of the one source/drain regions. Storage elements (e.g., 85) are included and are individually electrically coupled to individual of the conductive-via constructions. Individual of the conducting-via constructions and the individual conductive-via constructions comprise a conductive monocrystalline covering (e.g., 37) that is directly above and directly against the pillar top and that is circumferentially about and directly against the pillar sidewalls. The conductive monocrystalline covering is of the same crystallinity as the conductively-doped monocrystalline semiconductive material of the pillar. The conductive monocrystalline covering at least predominantly has greater conductivity-increasing-dopant therein than is at least predominantly in the pillar top.

In one embodiment, the individual conductive-via constructions comprise conducting material (e.g., 42) vertically between one of the storage elements and its conductive monocrystalline covering. Such conducting material is directly above and directly electrically coupled to its conductive monocrystalline covering. The conducting material is of different composition from that of its conductive monocrystalline covering.

Any other attribute(s) or aspect(s) as shown and/or described herein with respect to other embodiments may be used.

In one embodiment, memory circuitry (e.g., 8, 8b) comprises transistors (e.g., 25) individually comprising one source/drain region (e.g., 24) and another source/drain region (e.g., 26). The one and another source/drain regions individually comprise a pillar (e.g., 13*) comprising conductively-doped monocrystalline semiconductive material (e.g., 15). The pillar comprises a pillar top (e.g., 30) and pillar sidewalls (e.g., 31). A channel region (e.g., 27) is between the one and the another source/drain regions. A conductive gate (e.g., 22) is operatively proximate the channel region. Conducting-via constructions (e.g., 89) are included and are individually directly above and directly electrically coupled to the pillar of individual of the another source/drain regions. Digitlines (e.g., 40) are individually above and directly electrically coupled to a plurality of the conducting-via constructions. Conductive-via constructions (e.g., 82) are included and are individually directly above and directly electrically coupled to the pillar of individual of the one source/drain regions. Storage elements (e.g., 85) are included and are individually electrically coupled to individual of the conductive-via constructions. Individual of the conducting-via constructions and the individual conductive-via constructions comprising a conductive monocrystalline covering (e.g., 37) that is directly above and directly against the pillar top and that is circumferentially about and directly against the pillar sidewalls. An intermediate region (e.g., 50) is at an interface (e.g., 52) of the conductive monocrystalline covering with the pillar top and the pillar sidewalls. The intermediate region comprises chlorine, fluorine, and nitrogen individually at 1×10¹⁵ atoms/cm³ to 5×10²¹ atoms/cm³.

Any other attribute(s) or aspect(s) as shown and/or described herein with respect to other embodiments may be used.

Epitaxially growing material 33 in forming conductive monocrystalline coverings 37 as shown and described herein may be used to enlarge the targeting area for subsequent patterning for forming materials 34 and 80 thus perhaps increasing area for ohmic contact of another source/drain regions 26 and digitline structures 35 and of one source/drain regions 24 with storage elements 85. Although FIGS. 29-34 show perfect alignment of digitline structures 35 with original pillars 13y, such may not occur in practice and thereby with conductive monocrystalline coverings 37 providing additional x direction and y direction margin. Forming material 42 may be used to further enlarge x-y area for ultimately forming conductive material 80.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming pillars that project upwardly from a substrate and comprise conductively-doped monocrystalline semiconductive material. Individual of the pillars comprise either one source/drain region or another source/drain region of a transistor of individual memory cells of the memory circuitry being formed. Conductively-doped monocrystalline semiconductor material is epitaxially grown from a top and sidewalls of the individual pillars to form conductive monocrystalline coverings that are individually directly above the top and circumferentially about the sidewalls of the individual pillars. Digitlines are formed individually above and directly electrically coupled to a plurality of the individual pillars of the another source/drain regions through the epitaxially-grown conductive monocrystalline covering that is directly there-above. Storage elements of the individual memory cells are formed. The storage elements individually are above and electrically coupled to the individual pillars of the one source/drain regions through the epitaxially-grown conductive monocrystalline covering that is directly there-above.

In some embodiments, memory circuitry comprises transistors individually comprising one source/drain region and another source/drain region. The one and another source/drain regions individually comprise a pillar comprising conductively-doped monocrystalline semiconductive material. The pillar comprises a pillar top and pillar sidewalls. A channel region is between the one and the another source/drain regions. A conductive gate is operatively proximate the channel region. Conducting-via constructions are individually directly above and directly electrically coupled to the pillar of individual of the another source/drain regions. Digitlines are individually above and directly electrically coupled to a plurality of the conducting-via constructions. Conductive-via constructions are individually directly above and directly electrically coupled to the pillar of individual of the one source/drain regions. Storage elements are individually electrically coupled to individual of the conductive-via constructions. Individual of the conducting-via constructions and the individual conductive-via constructions comprise a conductive monocrystalline covering that is directly above and directly against the pillar top and that is circumferentially about and directly against the pillar sidewalls. The conductive monocrystalline covering is of the same crystallinity as the conductively-doped monocrystalline semiconductive material of the pillar. The conductive monocrystalline covering at least predominantly has greater conductivity-increasing-dopant therein than is at least predominantly in the pillar top.

In some embodiments, memory circuitry comprises transistors individually comprising one source/drain region and another source/drain region. The one and another source/drain regions individually comprise a pillar comprising conductively-doped monocrystalline semiconductive material. The pillar comprises a pillar top and pillar sidewalls. A channel region is between the one and the another source/drain regions. A conductive gate is operatively proximate the channel region. Conducting-via constructions are individually directly above and directly electrically coupled to the pillar of individual of the another source/drain regions. Digitlines are individually above and directly electrically coupled to a plurality of the conducting-via constructions. Conductive-via constructions are individually directly above and directly electrically coupled to the pillar of individual of the one source/drain regions. Storage elements are individually electrically coupled to individual of the conductive-via constructions. Individual of the conducting-via constructions and the individual conductive-via constructions comprise a conductive monocrystalline covering that is directly above and directly against the pillar top and that is circumferentially about and directly against the pillar sidewalls. An intermediate region is at an interface of the conductive monocrystalline covering with the pillar top and the pillar sidewalls. The intermediate region comprises chlorine, fluorine, and nitrogen individually at 1×10¹⁵ atoms/cm³ to 5×10²¹ atoms/cm³.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming pillars that project upwardly from a substrate and comprise conductively-doped monocrystalline semiconductive material, individual of the pillars comprising either one source/drain region or another source/drain region of a transistor of individual memory cells of the memory circuitry being formed;
epitaxially growing conductively-doped monocrystalline semiconductor material from a top and sidewalls of the individual pillars to form conductive monocrystalline coverings that are individually directly above the top and circumferentially about the sidewalls of the individual pillars;
forming digitlines that are individually above and directly electrically coupled to a plurality of the individual pillars of the another source/drain regions through the epitaxially-grown conductive monocrystalline covering that is directly there-above; and
forming storage elements of the individual memory cells, the storage elements individually being above and electrically coupled to the individual pillars of the one source/drain regions through the epitaxially-grown conductive monocrystalline covering that is directly there-above.

2. The method of claim 1 wherein the forming of the pillars comprises removing insulative material that surrounds the conductively-doped monocrystalline semiconductive material.

3. The method of claim 2 wherein the forming of the pillars comprises removing insulative material that is atop the conductively-doped monocrystalline semiconductive material.

4. The method of claim 3 wherein the removings each comprise etching.

5. The method of claim 4 wherein the insulative material comprises silicon nitride and silicon dioxide, the etching comprising etching the silicon nitride and the silicon dioxide selectively relative to the conductively-doped monocrystalline semiconductive material at the same time using the same etching chemistry.

6. The method of claim 4 wherein the insulative material comprises silicon nitride and silicon dioxide, the etching comprising temporal first, second, and third etchings;
the first etching removing some of the silicon nitride selectively relative to the silicon dioxide and the conductively-doped monocrystalline semiconductive material;
the second etching removing some of the silicon dioxide selectively relative to the silicon nitride and the conductively-doped monocrystalline semiconductive material; and
the third etching removing another some of the silicon nitride selectively relative to the silicon dioxide and the conductively-doped monocrystalline semiconductive material.

7. The method of claim 1 wherein the epitaxially growing forms the conductive monocrystalline coverings to at least predominantly have greater conductivity-increasing-dopant therein than is at least predominantly in the top of the individual pillars.

8. The method of claim 7 wherein the greater conductivity-increasing-dopant is by a factor of at least 10.

9. The method of claim 7 wherein the conductively-doped monocrystalline semiconductor material and the conductively-doped monocrystalline semiconductive material are of the same composition but for quantity of the conductivity-increasing-dopant.

10. The method of claim 9 wherein the same composition at least predominantly comprises elemental silicon.

11. The method of claim 1 wherein the epitaxially growing forms an intermediate region at an interface of individual of the conductive monocrystalline coverings with the top and the sidewalls of its pillar, the intermediate region comprising chlorine, fluorine, and nitrogen individually at 1×10¹⁵ atoms/cm³ to 5×10²¹ atoms/cm³.

12. The method of claim 1 wherein the epitaxially growing forms the conductive monocrystalline covering along a total of elevational length of the sidewalls of the pillars that are above the substrate.

13. The method of claim 1 wherein the epitaxially growing forms the conductive monocrystalline covering only along an uppermost portion of the sidewalls of the pillars that are above the substrate and thereby along less than a total of elevational length of the sidewalls of the pillars that are above the substrate.

14. Memory circuitry comprising:
transistors individually comprising:
one source/drain region and another source/drain region, the one and another source/drain regions individually comprising a pillar comprising conductively-doped monocrystalline semiconductive material, the pillar comprising a pillar top and pillar sidewalls;
a channel region between the one and the another source/drain regions; and
a conductive gate operatively proximate the channel region;
conducting-via constructions that are individually directly above and directly electrically coupled to the pillar of individual of the another source/drain regions;
digitlines that are individually above and directly electrically coupled to a plurality of the conducting-via constructions;
conductive-via constructions that are individually directly above and directly electrically coupled to the pillar of individual of the one source/drain regions;
storage elements that are individually electrically coupled to individual of the conductive-via constructions; and
individual of the conducting-via constructions and the individual conductive-via constructions comprising a conductive monocrystalline covering that is directly above and directly against the pillar top and that is circumferentially about and directly against the pillar sidewalls, the conductive monocrystalline covering being of the same crystallinity as the conductively-doped monocrystalline semiconductive material of the pillar, the conductive monocrystalline covering at least predominantly having greater conductivity-increasing-dopant therein than is at least predominantly in the pillar top.

15. The memory circuitry of claim 14 wherein the individual conductive-via constructions comprise conducting material vertically between one of the storage elements and its conductive monocrystalline covering, the conducting material being directly above and directly electrically coupled to its conductive monocrystalline covering, the conducting material being of different composition from that of its conductive monocrystalline covering.

16. The memory circuitry of claim 14 wherein the greater conductivity-increasing-dopant is by a factor of at least 10.

17. The memory circuitry of claim 14 wherein the conductively-doped monocrystalline semiconductor material and the conductively-doped monocrystalline semiconductive material are of the same composition but for quantity of the conductivity-increasing-dopant.

18. The memory circuitry of claim 17 wherein the same composition at least predominantly comprises elemental silicon.

19. The memory circuitry of claim 14 comprising an intermediate region at an interface of the conductive monocrystalline covering with the pillar top and the pillar sidewalls, the intermediate region comprising chlorine, fluorine, and nitrogen individually at 1×10¹⁵ atoms/cm³ to 5×10²¹ atoms/cm³.

20. Memory circuitry comprising:
transistors individually comprising:
one source/drain region and another source/drain region, the one and another source/drain regions individually comprising a pillar comprising conductively-doped monocrystalline semiconductive material, the pillar comprising a pillar top and pillar sidewalls;
a channel region between the one and the another source/drain regions; and
a conductive gate operatively proximate the channel region;
conducting-via constructions that are individually directly above and directly electrically coupled to the pillar of individual of the another source/drain regions;
digitlines that are individually above and directly electrically coupled to a plurality of the conducting-via constructions;
conductive-via constructions that are individually directly above and directly electrically coupled to the pillar of individual of the one source/drain regions;
storage elements that are individually electrically coupled to individual of the conductive-via constructions; and
individual of the conducting-via constructions and the individual conductive-via constructions comprising:
a conductive monocrystalline covering that is directly above and directly against the pillar top and that is circumferentially about and directly against the pillar sidewalls; and
an intermediate region at an interface of the conductive monocrystalline covering with the pillar top and the pillar sidewalls, the intermediate region comprising chlorine, fluorine, and nitrogen individually at 1×10¹⁵ atoms/cm³ to 5×10²¹ atoms/cm³.

21. The memory circuitry of claim 20 wherein the intermediate region comprises chlorine, fluorine, and nitrogen individually at 1×10¹⁸ atoms/cm³ to 5×10¹⁹ atoms/cm³.

22. The memory circuitry of claim 20 wherein the individual conductive-via constructions comprise conducting material vertically between one of the storage elements and the conductive monocrystalline covering, the conducting material being directly above and directly electrically coupled to the conductive monocrystalline covering, the conducting material being of different composition from that of the conductive monocrystalline covering.
